(19) United States
(12) Patent Application Publication
(10) Pub. No.: US 2007/0048628 A1
(43) Pub. Date: Mar. 1, 2007

(54) Plasmonic array for maskless lithography

(76) Inventor: Jeffrey L. Mackey, Boise, ID (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/218,098

(22) Filed: Sep. 1, 2005

(51) Int. Cl. G03F 1/00

(52) U.S. Cl. 430/5

(57) ABSTRACT

In various embodiments, a photolithography system comprises a spatial light modulator and a plasmonic lens array. The spatial light modulator comprises a plurality of pixels, and the plasmonic lens array comprises a plurality of plasmonic lenses. The pixels are optically aligned with the plasmonic lenses such that light from the pixels is substantially focused by the lenses. The plasmonic lenses each comprise an optical aperture and a plurality of metal features proximal to the aperture. The metal features have a dimension and arrangement configured to couple optical energy incident on one side of the plasmonic lens into plasmon excitation supported by the metal and to reemit optical energy through the aperture.

### BACKGROUND

1. Field of the Invention

The present teachings relate to photolithography apparatus and methods such as for use in fabricating semiconductor devices.

2. Description of the Related Art

Conventional photolithography systems employ a reticle or mask having a pattern that is to be replicated in a photoresist layer coated on a semiconductor wafer. The mask is imaged by projection optics onto the photoresist to expose portions of the photoresist to light in accordance with the pattern in the reticle. To implement a particular design for a semiconductor device therefore necessitates the fabrication of the mask having the customized pattern formed therein. Design and fabrication of the mask is complex and time-consuming. Method that shortens the path from device design to completion of a device on chip presents a significant advantage. Accordingly, photolithographic methods that do not require a mask are needed.

### SUMMARY

One embodiment of the invention comprises a photolithography system comprising an image formation device and a plasmonic lens array. The image formation device comprising a plurality of pixels and the plasmonic lens array comprises a plurality of plasmonic lenses. The pixels are disposed with respect to the plasmonic lenses such that light from the pixels is substantially focused by the lenses. In some embodiments, the image formation device comprises a spatial light modulator. In some embodiments, the image formation device comprises an array of light sources.

Another embodiment of the invention comprises a method of exposing a sample to patterned radiation. The method comprises spatially modulating a beam of light and propagating the modulated beam of light through a plurality of plasmonic lenses to focus the light.

Another embodiment of the invention comprises a photolithography system comprising means for producing a spatially modulated beam of light and means for focusing the beam of light. The focusing means couples optical energy into plasmonic modes and couples optical energy out of the plasmonic modes into a plurality of laterally separated foci.

Another embodiment of the invention comprises a method of fabricating an integrated circuit device on a semiconductor wafer. In this method, a material to be patterned is deposited over the semiconductor wafer. A photoresist is deposited on the material. A spatially modulated beam of light is produced and the beam of light is focused onto the photoresist using a plurality of apertures. Portions of the photoresist are thereby exposed. Each of the apertures is proximal to a periodic arrangement of metal features having a period of between about 20 nanometers and 500 nanometers. The photoresist is developed, the material is etched, and the photoresist is removed.

Another embodiment of the invention comprises a method of fabricating a photolithography system. This method comprises providing an image forming device comprising a plurality of pixels and providing an array comprising a plurality of optical apertures. Each aperture is surrounded on opposite sides by metal features. The outermost metal features for adjacent apertures are separated by no more than about one micron. The method further comprises aligning the pixels with the optical apertures.

Another embodiment of the invention comprises a photolithography system comprising an image formation device comprising a plurality of pixels and an array comprising a plurality of optical apertures surrounded by a plurality metal features on opposite sides of each of the apertures. Adjacent of the optical apertures have an average center-to-center spacing of no more than about 10 microns. The pixels in the image formation device are optically aligned with the apertures in the array.

### BRIEF DESCRIPTION OF THE DRAWINGS

FIG. 1 is a perspective view schematically illustrating a portion of a maskless photolithography system comprising a spatial light modulator and a plasmonic lens array.

FIG. 2 is a plan view of the plasmonic lens array schematically depicting a plurality of plasmonic lenses configured to concentrate light into a plurality of point foci.

FIG. 3 is a cross-sectional view through the line 3-3 in plasmonic lens array in FIG. 2 showing one of the plasmonic lenses.

FIG. 4 is a schematically diagram of a maskless photolithography system employing a reflective spatial light modulator.

FIGS. 5 and 6 are plan views of plasmonic lens arrays comprising plasmonic lenses configured to produce vertical and horizontal line foci.

### DETAILED DESCRIPTION OF VARIOUS PREFERRED EMBODIMENTS

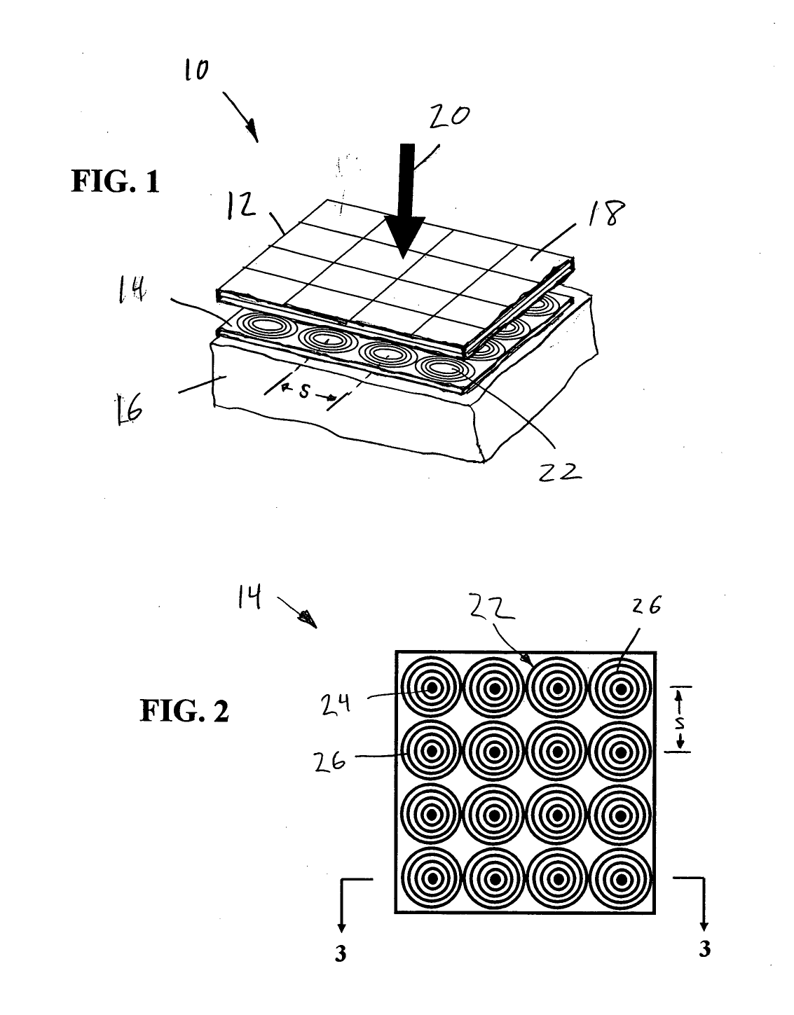

FIG. 1 shows an apparatus 10 comprising a spatial light modulator 12 and a plasmonic lens array 14 disposed over a semiconductor wafer 16. The spatial light modulator 12 comprises a plurality of pixels 18 each comprising at least one light modulator. Light, represented by arrow 20, propagates through the spatial light modulator 12. The pixels 18 can be selectively activated to control light propagation through the pixels. Spatial light patterns can thereby be formed. Examples of such spatial light modulators include liquid crystal spatial light modulators and faraday rotators, although the type of spatial light modulator is not limited to those described herein as other types of spatial light modulator devices both well known in the art and yet to be devised may be used.

The plasmonic lens array 14 comprises a plurality of plasmonic lenses 22 that focus light propagated through the spatial light modulator 12 onto the semiconductor wafer 16. The plasmonic lenses 22 are shown aligned with the pixels 18 such that light passing through one of the pixels 18 is focused by a corresponding one of the plasmonic lenses. The plasmonic lenses 22 have a center-to-center spacing, S, that may match the center-to-center spacing of the pixels 18 in spatial light modulator 12 in some embodiments. The average center-to-center spacing may, for example, be about 10 micron or less in some embodiments. In other embodiments, the average center-to-center spacing may, for example, be about 5 micron or less or smaller. Values outside these ranges are also possible. Also, in certain embodiments optics may be disposed between the spatial light modulator 12 and the plasmonic lens array 14.

Additionally, FIG. 1 shows sixteen pixels in the spatial light modulator 12 for illustrative purposes only. The spatial light modulator 12 may comprise any number of pixels 18. Similarly, the plasmonic lens array 14 can comprise any number of plasmonic lenses 22.

In various preferred embodiments, the semiconductor wafer 16 is disposed in the near field of the plasmonic lenses 22. The semiconductor wafer 16 may be supported by a wafer stage (not shown). The wafer stage may be configured to position the semiconductor wafer 16 in the near field of the plasmonic lenses 14. A feedback system (also not shown) may be used to maintain the distance between the plasmonic lenses 22 and the semiconductor wafer 16 such that the semiconductor wafer 16 is in the near field of the plasmonic lenses 22. The wafer stage and/or the plasmonic lens array 14 may be moved to establish the suitable distance therebetween.

A top view of the plasmonic lens array 14 is shown in FIG. 2. Each of the plasmonic lenses 22 comprises an aperture 24 and a plurality of metal features 26. In the embodiment shown in FIG. 2, the aperture 24 is circular and the metal features 26 are annular. The annular features 26 are concentric and centered about the aperture 24. Four annular features 26 are shown in each lens 22 although other numbers of rings may be used. In various embodiments, however, high packing density of the plasmonic lenses 22 in the plasmonic lens array 14 is desired so as to provide high resolution. Accordingly, the number of features 26 and their size is small. In some embodiments, for example, the number of annular features 26 is less than 5.

The aperture 24 is also small, for example, less than the wavelength of light propagating therethrough in certain embodiments. Transmission of light through sub-wavelength sized apertures is generally limited and light is diffracted in all directions by the aperture. The metal features 26, however, assist in coupling optical energy through the aperture 24. Without subscribing to any particular theory, optical energy incident on the metal features 26 may be coupled into plasmons modes which are excited in the metal as a result of the incident light. This optical energy may be coupled out on the other side of the plasmonic lens 22. This result is enhanced throughput through the sub-wavelength sized aperture 24. See, e.g., H. J. Lezec et al, “Beaming Light from a Subwavelength Aperture,” Science, Vol. 297, Aug. 2, 2002, which is incorporated herein by reference in its entirety. See also U.S. Pat. Nos. 6,539,156 and 6,862,396 which are also incorporated herein in their entirety.

Accordingly, the metal features 26 have a dimension and arrangement to couple optical energy into plasmon excitation. In certain embodiments, for example, the metal features 26 have a size less than the wavelength of the incident light that is to be propagated through the aperture 24. The metal features may also have a spacing of about a wavelength or less. The metal features 26 may be periodic and have a periodicity suitable for coupling the optical energy into the plasmons. In the embodiment shown in FIGS. 1 and 2, the aperture 24 and metal features 26 are circularly or rotationally symmetric and provides a point focus. The light incident on this lens 22 having a circular aperture 24 and circularly symmetric features 26 is focused into a substantially circular spot have a small size. Other configurations and arrangements are possible.

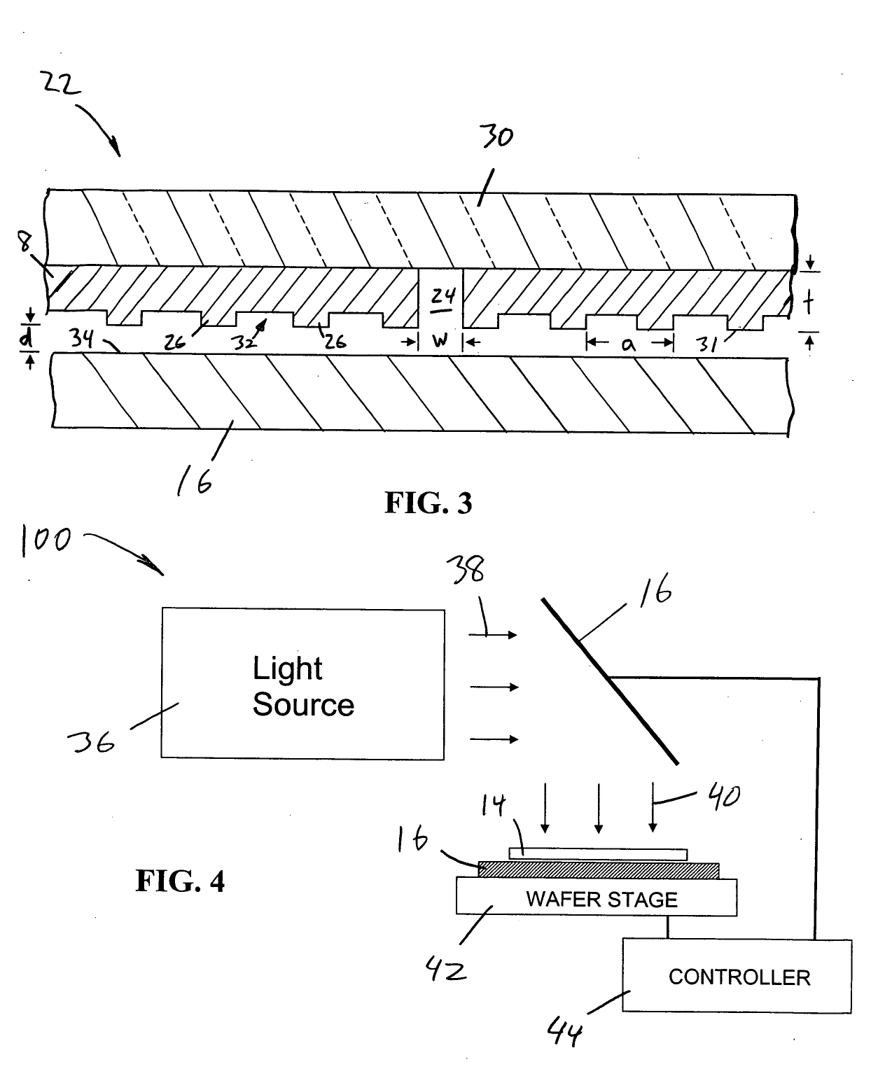

A cross-section through one of the lenses 22 in the plasmonic lens array 16 is shown in FIG. 3. As schematically illustrated, the plasmonic lens array 16 comprises a metal layer 28 formed over a glass or quartz substrate 30. The metal layer 28 may comprise, for example, silver (Ag), copper (Cu), gold (Au), aluminum (Al), tantalum (Ta), chromium (Cr) or other metals or metal alloys that support excitation of plasmons. The substrate 30 may comprise materials other than glass or quartz that are substantially transmissive to light of the wavelength of operation. The aperture 24 comprises an opening in the metal layer 28. The metal features 26 comprises surface features in the surface 31 of the metal layer 28. In the embodiment shown, the metal feature 26 are formed from grooves 32 in the metal layer 28. Although the surface 31 of the metal layer 28 is not covered, in other embodiments a material such as a material that is substantially optically transmissive to the wavelength of light to be propagated through the lens 22 may be included on the metal layer. This layer of material, however, may be thin. Additionally, although the metal layer 30 is disposed directly on the glass or quartz substrate 30, one or more layers, for example, of material that is substantially optically transmissive to the wavelength of the light may be disposed therebetween.

The metal layer 30 has a thickness, t, that is between about 10 and 500 nanometers in certain embodiments. For example, the thickness, t, may be about 350 nanometers. The surface features 26 in the metal layer 30 may have a wide range of dimensions, generally with an average periodicity of between 200 nanometers and 800 nanometers, e.g., about 500 nanometers in some embodiments. Trench widths will generally range from about 100 nm to about 500 nm and trench depth will range from about 10 nm to about 100 nm. The aperture 24 may have a diameter of about 250 nanometers but may be larger or smaller. Although only one lens 22 is shown in the cross-section in FIG. 3, the lens array 14 comprises multiple lenses and thus one or more lenses may be adjacent to the lens shown in FIG. 3. In various embodiments, the lenses 22 are packed close together. For example, the outermost feature 26 on one lens 14 may be less than about 200 to 500 nm, nominally less than about 1 micron from its nearest neighbor.

As discussed above, the dimensions and configuration may be selected to enable incident light to be coupled into and out of plasmons supported by in the metal layer 29 and to enhance the transmission of optical energy through the aperture 24. The dimension and configuration may be selected such that the plasmonic lens 22 substantially focus the light propagated therethrough. Different configurations and designs, as well as dimensions outside the ranges provided herein may also be used in other embodiments. For example, the features 26 may have different shape, size, and spacing. The apertures 24 may also have different shape, size, and spacing.

FIG. 3 also shows the plasmonic lens array 22 separated from the semiconductor wafer 16 by a distance, d. As discussed above, in certain embodiments the semiconductor wafer 16 is in the near field of the plasmonic lens 22 so as to provide a tight focus. In particular, the semiconductor wafer 16 may comprise a photoresist layer having a surface 34 and this distance, d, is about 400 nm or less from the surface of the resist layer. This distance, d, is from the wafer-side edge of the metal surface to the resist top surface. The thickness of the quartz/glass substrate will be thicker than this distance, d, in various embodiments. Accordingly, the metal layer 28 is formed on a side of the quartz/glass substrate 30 that faces the semiconductor wafer 16 in certain embodiments. Values outside these ranges, however, are also possible.

Other configurations may also be employed. Although the metal layer 28 is shown in FIG. 3 as spaced apart from the semiconductor wafer 16, e.g., by air, fluid may be in this region. In some embodiments, the plasmonic lens array 14 and the metal layer 28 might be disposed on the wafer 116. Also, although the metal features 26 are shown as periodic and spaced by a constant separation, the features need not be periodic. The metal features 26 can also be shaped differently. For example, the features 26 may be more rounded, may be triangular, or any other shape. The metal features 26 may be irregularly shaped and can vary from one feature to the next.

In addition, although the optical aperture 24 is shown as an open region, the optical aperture 24 may be filled with material that is substantially optically transmissive to the light. A layer of material that is substantially optically transmissive to the wavelength of light being used may also cover the metal layer 28. This layer of material may cover and/or fill the opening in the metal layer 28 that defines the optical aperture 24. Other variations in the plasmonic lenses 22 and the positioning of the plasmonic lenses 22 with respect to the semiconductor wafer 16 are also possible.

The plasmonic lens array 14 may be fabricated by depositing metal on the glass or quartz substrate 30 to form the metal layer 28. This metal layer 28 may be patterned, for example, using ion beam etching, to create the metal features 26. Other methods may also be employed to fabricate the plasmonic lenses 22.

In operation, light is incident on the plasmonic lens 22, and in particular, on the metal layer 28. The metal features 26 have a dimension and arrangement to facilitate coupling of optical energy into plasmons supported by the metal layer 28. In certain embodiments, the spacing of the substantially periodic metal features 26 is selected to provide coupling into the plamonic modes. Optical energy coupled into the plasmonic modes is also coupled out of the plasmonic modes into light on the other side of the metal layer 28 that propagates away therefrom. The result is that a substantially larger amount of light is propagated through the lens 22 than if the lens comprised the aperture 24 alone. The metal features 26 can also be arranged to substantially focus the light, for example, into a tight point focus.

FIG. 4 shows a photolithography system 100 having a different configuration than shown in FIG. 1. In particular, the spatial light modulator 12 comprises a reflective spatial light modulator rather than a transmissive spatial light modulator. Examples of reflective spatial light modulators include liquid crystal spatial light modulators, tiltable mirrors, and faraday rotators, although the type of spatial light modulator is not limited to those described herein as other types of spatial light modulator devices both well known in the art and yet to be devised may be used. As discussed above, the spatial light modulator 12 comprises an addressable array of pixels 18 having controllable states that can be altered to produce the desired light pattern. In certain embodiments, selected pixels can be turned on or off to reflect light to or way from the plasmonic array 14 and semiconductor wafer 16.

FIG. 4 also shows a light source 36 that provides light, represented by arrows 38 and 40 for illuminating the semiconductor wafer 16. The wavelength of the light source 36 may be suitable for exposing a particular photosensitive material used to pattern the semiconductor wafer 16. This wavelength may, in general, range from about 100 to about 800 nanometers, extending from the extreme ultraviolet to through the visible spectrum. For example, light sources in the visible spectrum between 400 and 800 nanometer may be used although shorter wavelength can be used to obtain increased resolution. Advantageously, however, the method described herein can be used to provide high resolution patterning using relatively inexpensive light sources. For example, relatively inexpensive high pressure lamps providing light at about 365 and 580 nanometers can be used. Other types of light sources that output light having spectral distributions centered at other wavelengths may also be employed.

The light 38, 40 from the light source 36 is directed on an optical path that includes the spatial light modulator 12, the plasmonic lens array 14, and the semiconductor wafer 16. As shown in FIG. 4, the light 38 is incident on the spatial light modulator 16 and is reflected therefrom toward the plasmonic lens array 14. The spatial light modulator 12 pixelates the beam of light 40, for example, by reflecting light from certain pixels and not reflecting light from other pixels depending on the state of the pixels or reflecting light toward or away from the plasmonic lens array 14 depending on the state of the pixels. Other techniques may also be used to pixelate the beam of light 40 that reaches plasmonic lens array 14 and that is used to expose the semiconductor wafer 16.

As described above, the plasmonic lens array 14 focuses the light 40 onto the semiconductor wafer 16. In certain preferred embodiments, light 40 from the pixels 18 in the spatial light modulator are directed onto respective plasmonic lenses 22 in the plasmonic lens array 14 and are focused down to respective point foci on the semiconductor wafer 16. In various embodiments, these point focus are small and are spaced close together to provide for high resolution patterning of the semiconductor wafer 16. In particular, light patterns having high resolution may be formed on the semiconductor wafer 12.

FIG. 4 also shows the semiconductor wafer 16 supported by a wafer stage 42. As described above, this wafer stage 42 may be used to establish the appropriate distance between the plasmonic lens array 14 and the semiconductor wafer 16, for example, such that the semiconductor wafer 16 is in the near field of the plasmonic lenses 22. The wafer stage 42 may also be configured to move laterally to translate the semiconductor wafer 16 with respect to the plasmonic lens array 14. In certain embodiments, the photoresist-coated substrate 16 is scanned with respect to the plasmonic array 14. The spatial light modulator 16 controls the incident light on each of the plasmonic lenses 22 to provide on, off, or grayscale levels of illumination of the photoresist. A computer database containing pattern information may be used to calculate the state of the pixels 18 in the spatial light modulator 12 as the semiconductor wafer 16 is scanned to produce the desired pattern. The state of the pixel 18 is varied as the semiconductor wafer 16 is scanned to produced a varied pattern in the semiconductor wafer 16.

FIG. 4 shows a controller 44 for controlling the wafer stage 42 and the spatial light modulator 16. This controller 44 may comprise a computer, computer network, one or more microprocessors or any electronics or apparatus suitable for controlling the spatial light modulator 12 and/or wafer stage 42. In other embodiments, the plasmonic lenses 22, the spatial light modulator 12, and possibly the light source 36 or any combination thereof may be shifted, translated, moved or otherwise varied to alter the position of the light with respect to the semiconductor wafer 16. Also, although the semiconductor wafer 16 is shown disposed on the wafer stage 42 with the plasmonic lens array 14 above the semiconductor wafer 16, the orientation of the semiconductor wafer with respect to the plasmonic array may be different. For example, the semiconductor wafer 16 secured to the wafer stage 42 may be disposed over the plasmonic array 14.

Other configurations are also possible. For example, the photolithography apparatus 100 may be configured differently and may include additional components. The order and arrangement of the components may be different and some of the components may be removed. The individual components themselves may be different. For example, a wide range of light sources 36, spatial light modulators 12, plasmonic lens arrays 14, wafer stages 42, and controllers 44 may be used.

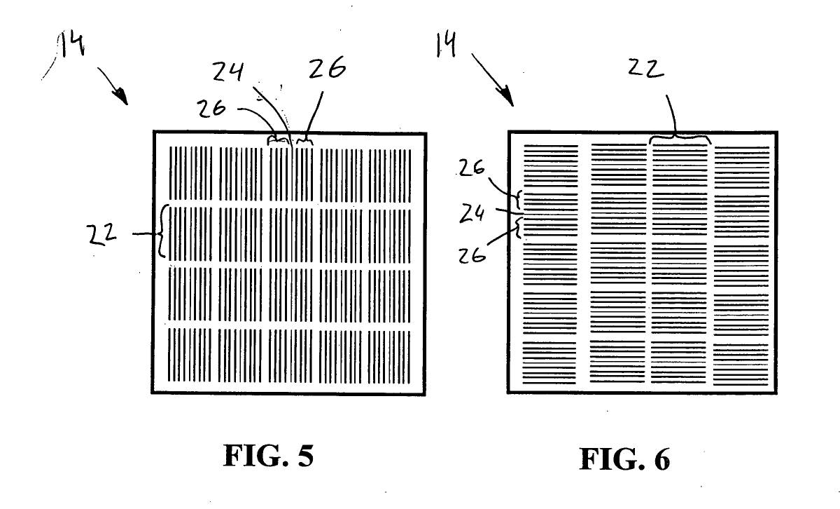

FIGS. 5 and 6 show plasmonic lens arrays 14 comprising plasmonic lenses 22 having differently shaped apertures 24 and metal features 26. Instead of the circular apertures 24 and annular metal features shown in FIG. 2, the plasmonic lenses 22 in FIGS. 5 and 6 comprise elongated apertures and metal features. In particular, the aperture 24 comprises an elongated slit. This slit may be substantially rectangular, for example. The metal features 26 are also linear and may be substantially rectangular. The lenses 22 in FIG. 5 are rotated with respect to the plasmonic lenses 22 in FIG. 6. In particular, the aperture 24 and metal features 26 are vertical in FIG. 5 and horizontal in FIG. 6. The plasmonic lenses 22 in FIG. 5 produce separate line foci that are vertical and the plasmonic lenses in FIG. 6 produce separate line foci that are vertical. The plasmonic lens arrays 14 in FIGS. 5 and 6 can be superimposed to produce a plurality of separate point foci much light the plasmonic array shown in FIG. 2.

Plasmonic lenses 22 having different configurations and that produce different foci are also possible. The aperture 24 and the metal features 26 may be oriented different. For example, the aperture 24 and metal features 26 may be oriented at an angle other than horizontal or vertical with respect to the plasmonic array 14. The number of metal features 26 may also vary. In certain embodiments, however, the number of metal features is reduced to reduce the center-to-center spacing of the plasmonic lenses 22 and provide high packing density of the plasmonic lenses 22 in the lens array 14 and increase pattern resolution. For example, five or less metal features may be located on either side of the aperture 24 although in other embodiments, the number may be different.

Also, the shape of the aperture 24 and metal features 26 may be different. Although straight linearly shaped apertures 24 and features 26 are shown the aperture and features may be other than straight. For example, the aperture 24 and features 26 may be rounded, curved, or rectilinear but not straight. The apertures 24 and metal features 26 may vary in thickness, shape, separation from adjacent features, etc. along the length of their length. Irregular apertures 24 and features 26 may be used and the aperture and features need not all be similar or the same. The features 26 need not be periodic and may be spaced irregularly.

Additionally, in certain embodiments, the lenses 22 may differ across the lens array 14. The position, number, arrangement, and type of plasmonic lenses 22 (and the type of resultant foci) may vary for a particular plasmonic lens array 14. The number and type of plasmonic arrays 14 that may be used in the photolithography system 100 may also vary.

Although spatial light modulators can be used to produce a modulated beam of light, other types of image formation devices can be used. For example, an emissive display comprising a plurality of light source or light emitters such as light emitting diodes (LEDs) can be used in some embodiments. The image formation devices may include a plurality of pixels that are separately addressable so as to alter the states of the individual pixels. In the case where the image formation device comprises an array of light emitters, for example, different light emitters can be selectively activated or their emissions can be otherwise changed to produce a spatially modulated beam and a desired spatial pattern. Other image formation devices and configurations can also be used.

The apparatus and methods described herein advantageously enable patterning of semiconductor wafers 16. Photosensitive material such as photoresist formed on a surface of the semiconductor wafer can be exposed and patterned. Such processes may be used to pattern metal, semiconductor, and insulating layers and to control doping or alloying of portions of such layers as is well known in the art. The methods and apparatus can be used in a wide range of other semiconductor device fabrication applications as well.

Although the apparatus and methods described above have been discussed with regards to photo-lithographically patterning a semiconductor wafer 16, the apparatus and methods may be used in other applications, for example, to pattern other types of samples or products. Still other applications are possible.

Advantageously, high resolution, maskless lithography can be provided; although, if needed, an additional mask as well as low resolution systems could be used. One advantage of using a maskless system, however, is to simplify the fabrication process from design concept to completion of product. The steps of producing a mask or reticle can be eliminated thereby saving a substantial amount of delay and reducing cost.

Various embodiments of the invention have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

1. A photolithography system comprising:
an image formation device comprising a plurality of pixels; and
a plasmonic lens array comprising a plurality of plasmonic lenses,
wherein said pixels are disposed with respect to said plasmonic lenses such that light from said pixels is substantially focused by said lenses.

2. The system of claim 1, wherein said image formation device comprises a spatial light modulator.

3. The system of claim 1, wherein said image formation device comprises an array of light sources.

4. The system of claim 1, wherein said plasmonic lenses have an average center-to-center spacing of about 10 micrometers or less.

5. The system of claim 4, wherein said plasmonic lenses have an average center-to-center spacing of about 5 micrometers or less.

6. The system of claim 1, wherein each of said plasmonic lenses comprises an optical aperture and a plurality of metal features proximal to said aperture.

7. The system of claim 6, wherein said aperture is substantially circular.

8. The system of claim 6, wherein said aperture comprises an elongated slit.

9. The system of claim 6, wherein said aperture has a width of about 400 nanometers of less.

10. The system of claim 9, wherein said aperture has a width of about 100 nanometers of less.

11. The system of claim 6, wherein the apertures for adjacent plasmonic lenses have an average center-to-center spacing of about 10 micrometers or less.

12. The system of claim 11, wherein the apertures for adjacent plasmonic lenses have an average center-to-center spacing of about 5 micrometers or less.

13. The system of claim 6, wherein said metal features have a dimension and arrangement configured to couple optical energy incident on one side of said plasmonic lens into plasmon excitation supported by the metal and to reemit optical energy through said aperture.

14. The system of claim 6, wherein said metal features are periodic.

15. The system of claim 6, wherein said metal features comprise substantially concentric annular rings.

16. The system of claim 15, wherein one of said plasmonic lenses contains no more than five concentric annular rings.

17. The system of claim 6, wherein said metal features comprise a plurality of elongate linear features on opposites sides of said aperture.

18. The system of claim 17, wherein one of said plasmonic lenses contains no more than five of said elongate linear features on one side of said aperture.

19. The system of claim 6, said wherein metal features have an average center-to-center spacing of less than about 600 nanometers.

20. The system of claim 2, further comprising a light source that emits visible or ultraviolet light having a center wavelength, said light source and said plasmonic lens array forming an optical path with said spatial light modulator in said optical path between said light source and said plasmonic lens array.

21. The system of claim 20, wherein said spatial light modulator is a transmissive spatial light modulator.

22. The system of claim 20, wherein said spatial light modulator is a reflective spatial light modulator.

23. The system of claim 20, wherein each of said plasmonic lenses comprises an optical aperture having an aperture size that is less than said center wavelength.

24. The system of claim 20, wherein each of said plasmonic lenses comprises a plurality of metal features and said metal features have a periodicity of said wavelength or less.

25. The system of claim 1, further comprising a wafer stage configured to position a wafer in the near field of said plasmonic lenses.

26. The system of claim 25, wherein said wafer stage is configured to be scanned laterally with respect to said plasmonic lens array.

27. The system of claim 25, further comprising a feedback system that is configured to position the wafer in the near field of said plasmonic lenses.

28. The system of claim 25, wherein said wafer stage is configured to position the wafer about 400 nanometers or less from said plasmonic lenses.

29. The system of claim 1, further comprising a feedback system that is configured to provide a distance between a wafer and the plasmonic lenses of about 400 nanometers or less.

30-62. (canceled)
